(19) United States
(12) Patent Application Publication
(10) Pub. No.: US 2018/0122625 A1
(43) Pub. Date: May 3, 2018

(54) SAMPLING A COMPOSITE SIGNAL RELATING TO A PLASMA PROCESS

(71) Applicant: TRUMPF Huettinger GmbH + Co. KG, Freiburg (DE)

(72) Inventors: Andre Grede, Freiburg (DE); Christian Bock, Freiburg (DE); Nikolai Schwerg, Genève (CH)

(21) Appl. No.: 15/856,199

(22) Filed: Dec. 28, 2017

Related U.S. Application Data
(63) Continuation of application No. PCT/EP2016/065335, filed on Jun. 30, 2016.

(30) Foreign Application Priority Data
Jun. 30, 2015 (DE) 102015212242.5

(51) Int. Cl. H01J 37/32; G01R 23/167

(52) U.S. Cl. CPC H01J 37/32926; G01R 23/167

(57) ABSTRACT

Methods and devices for sampling a composite signal relating to a plasma process are provided. The composite signal has at least one plasma signal of interest and superimposed by at least one interfering signal. The methods include identifying the at least one interfering signal, digitalizing the composite signal by sampling the composite signal at a sampling frequency, and varying the sampling frequency during an operation of the plasma process according to at least one of a frequency of the at least one plasma signal of interest and a frequency of the at least one interfering signal.

### CROSS-REFERENCE TO RELATED APPLICATIONS

This application is a continuation of and claims priority under 35 U. S.C. §120 from PCT Application No. PCT/EP2016/065335 filed on Jun. 30, 2016, which claims priority from German Application No. DE 10 2015 212 242.5, filed on Jun. 30, 2015. The entire contents of each of these priority applications are incorporated herein by reference.

### TECHNICAL FIELD

The invention relates to methods and devices for sampling a composite signal relating to a plasma process, the composite signal including at least one plasma signal of interest on which at least one interfering signal is superimposed.

### BACKGROUND

Devices and methods for sampling plasma process signals are known from the following documents for example: US 2012/0099684 A1, U.S. Pat. No. 8,064,560 B2, U.S. Pat. No. 5,565,737 A.

Industrial plasma processes are excited by one or more power signals. For example, a plasma process can be excited by one or more high-frequency power signals. High-frequency power signals of this kind have what is known as a fundamental frequency, e.g., 13.56 MHz. To control the plasma process, it is also conceivable, however, for the fundamental frequency of the high-frequency power signal to be varied in a frequency range.

When generating the high-frequency power signal, or also when the high-frequency power signal routed to the plasma process is reflected, signals that have a frequency different from the fundamental frequency may result. For example, signals can occur at the harmonics of the fundamental frequency. If the plasma process is excited by a plurality of power signals (excitation signals), mixed products of the frequencies of the excitation signals may also result. All these signals taken together are referred to as a composite signal. If a signal relating to the plasma process is sampled, a composite signal of this kind is generally sampled.

Plasma processes can be controlled using digital signal processing. Signals at the fundamental frequency, signals at the harmonics, or signals at mixed frequencies can be used for monitoring the plasma process. For example, it is possible to identify, from monitoring signals of this kind, whether an arc has developed in the plasma process. These are signals that relate to the plasma process and that are of interest because they can be used for further analysis.

The harmonics of the fundamental frequency, and further plasma excitation frequencies, make it more difficult to use analogue/digital convertors (A/D convertors) having a usually fixed sampling rate for digital monitoring and control of industrial plasma processes. Analogue filtering is therefore often used. If, however, the harmonics or signals at other frequencies are also to be monitored, the sampling rate (sampling frequency) required is disproportionately high. In addition, alias frequencies are a significant source of interference.

The sampling frequency conventionally required is more than twice the highest occurring signal frequency. If higher harmonics are to be monitored, the sampling frequency has to be selected to be correspondingly high, which makes the necessary A/D converter expensive and the signal processing complex.

Alternatively, a plurality of A/D converters can be arranged downstream of a plurality of analogue band-pass filters. Since there is still just one frequency here, slight undersampling is also possible, in which the requirement for the sampling frequency to be more than twice the signal frequency (frequency of the signal of interest) is no longer met. Instead, an image frequency of the signal of interest appears in the digital baseband.

If, for example for reasons of cost or complexity, undersampling is to take place for a plurality of signals at different frequencies (fundamental frequency, harmonics, and/or mixed products of frequencies), it should be ensured that no image frequencies or the reflected counterparts thereof overlap. For this purpose, all the frequencies in question must be known from the outset.

This is often not the case, however, for example in applications in which a plasma process is excited by a high-frequency power signal of 13.56 MHz and, simultaneously, external excitation occurs at approximately 40 MHz having an unknown exact frequency.

### SUMMARY

The present disclosure provides methods and devices for sampling composite plasma signals of interest of a plasma process without the influence of interfering signals. The composite signal includes at least one plasma signal of interest on which at least one interfering signal is superimposed. The methods include: identifying the at least one interfering signal, digitizing the composite signal by sampling the composite signal at a sampling frequency, and varying the sampling frequency during operation of the plasma process in dependence on a frequency of at least one plasma signal of interest and/or a frequency of the at least one interfering signal.

A plasma signal of interest relating to a plasma process is a signal that occurs during the plasma process and that is to be determined, for example, for analyzing or controlling the plasma process. For example, the plasma signal of interest can be a high-frequency power signal, by which the plasma process is excited at a fundamental frequency. It can also be a harmonic of the high-frequency power signal. Signals having a mixed frequency can also be plasma signals of interest, e.g., signals that occur when a plasma process is excited by different power signals. The term “plasma signal of interest” is used herein to make a distinction from signals that relate to the plasma process, but are not of interest to a user. The composite signal can include one or more plasma signals of interest, on each of which one or more interfering signals can be superimposed. The composite signal can thus be a mixture of a plurality of plasma signals of interest and a plurality of interfering signals.

In signal processing, “undersampling” refers to the digitization (sampling) of a desired signal at a sampling frequency that is less than twice the (highest) frequency of the desired signal. In the digital representation, signals of this kind arise from higher Nyquist zones than those of mirror images in the baseband (the first Nyquist zone). The first Nyquist zone refers to a frequency range up to half the sampling rate. The second Nyquist zone refers to a frequency range from half the sampling rate to the full sampling rate. The third Nyquist zone refers to a frequency range from the full sampling rate to one and a half times the sampling rate, and so on.

As used herein, an “interfering signal” is understood to be a signal that is superimposed on a plasma signal of interest. Undersampling the plasma signal of interest and/or the interfering signal can result in frequency superimposition of the interfering signal on the plasma signal of interest. If such frequency superimposition occurs, there can be said to be a distorted plasma signal of interest. The interfering signals can be external interfering signals of an unknown frequency. The plasma process can, however, also be excited by harmonics of a high-frequency power signal. For example, a harmonic can be a plasma signal of interest if the harmonics are to be analyzed for specific occurrences in the plasma process, but a harmonic can also be an interfering signal, for example for a signal at the fundamental frequency that excites the plasma process.

Both the at least one plasma signal of interest and the interfering signal can vary in a frequency range. For example, for the purpose of process control, the frequency of a high-frequency power signal that excites the plasma process can be varied.

The interfering signal can be identified by calculation or experimentally. Possibilities for determining or identifying the interfering signal will be explained below.

Varying the sampling rate makes it possible to determine individual signals and then to select a sampling rate at which only the desired signals, e.g., the plasma signals of interest, are detected.

If the sampling rate is varied, un-mirrored frequencies below the Nyquist rate, e.g., in the first Nyquist zone or below half the sampling frequency (fs), do not change. Furthermore, viewed in absolute terms, frequencies that are simply mirrored at fs/2 in the first mirror region (second Nyquist zone) change in the same manner as the sampling frequency. Viewed in absolute terms, frequencies that are simply mirrored at the sampling frequency (third Nyquist zone) change in the exact opposite manner to the sampling frequency. Viewed in absolute terms, frequencies in the fourth Nyquist zone change twice as quickly as the sampling rate. Changing the sampling rate thus makes it possible to select a sampling frequency at which the plasma signals of interest occur without superimposition.

A plurality of plasma signals of interest can be determined or detected at the same sampling frequency. In some examples, signals at the fundamental frequency and signals at harmonics of the fundamental frequency can be sampled or detected at the same sampling rate. This significantly simplifies the architecture of the signal processing in comparison with the prior art.

The at least one plasma signal of interest and/or the at least one interfering signal can be determined or detected in a Nyquist zone that is higher than the first Nyquist zone. A lower sampling rate can thus be selected.

The digital representation of the frequency of the at least one plasma signal of interest and the frequency of the at least one interfering signal can be determined. In the digital representation, only frequencies of signals in the first Nyquist zone are maintained, while frequencies from the higher Nyquist zones, e.g., having frequencies of greater than fs/2, are Nyquist mirror images (alias) of the actual frequencies.

When frequencies of the plasma signal and interfering signal are known, the sampling rate (sampling frequency) can be determined by calculation.

Furthermore, the interfering signal can be identified by looking at the digital representation, e.g., the spectrum. This again makes it possible to deliberately vary the sampling frequency to be able to determine the plasma signal of interest free of interfering signals.

The digital representation of the frequencies of the at least one plasma signal of interest and of the at least one interfering signal can be identified by at least one frequency sweep of the sampling frequency at the start of operation of the plasma process. These measures, too, make it possible to determine frequencies of interfering signals.

The digital representation of the frequencies of the at least one plasma signal of interest and of the at least one interfering signal can be identified by repeated frequency sweeps of the sampling frequency during operation of the plasma process. Interfering signals that occur at different stages of the operation of the plasma process can thus be taken into account when determining the sampling frequency.

The digital representation of the frequencies of the at least one plasma signal and of the at least one interfering signal can be identified by modulating the sampling frequency. If the sampling frequency is modulated at a specific frequency deviation, it is thus possible to identify, from the size and the sign (the direction) of the resulting frequency deviation on the digitized signal, which Nyquist zones the signal originates from and what actual frequency the signal had before sampling, even if the frequency is higher than fs/2. It is thus possible to easily identify the different carrier waves, harmonics, and mixed products.

The sampling frequency can be modulated continuously or just occasionally, e.g., at the start of the plasma process, to identify the interfering signals. The possible frequency modulation of the frequencies of the plasma signals of interest can be taken into account during the subsequent signal processing. If the frequencies of the interfering signals have been identified, the sampling frequency can be shifted such that the plasma signals of interest can be digitized in the spectrum without mutually overlapping. This optimum sampling frequency can be determined either by identifying all occurring signals and by subsequent calculation, or experimentally, for example by a frequency sweep of the sampling frequency together with simultaneous modulation.

The digital representation of the frequencies of the at least one plasma signal and of the at least one interfering signal can be identified by frequency or amplitude modulation of a high-frequency power signal exciting the plasma process. If, for example, the frequency of the high-frequency power signal changes by a specific frequency deviation, the original frequency of the monitored signal can be reconstructed in the digital representation thereof by determining the frequency deviation of the monitored signal, since the size and/or sign (direction) of the deviation change with each Nyquist zone. It is thus possible for a sampling rate to be selected, using which the plasma signal can be monitored without interference.

Viewed in absolute terms, the sampling rate can be tracked with an interfering signal. The distance between the at least one plasma signal of interest and the interfering signal remains the same.

The sampling frequency can be tracked with the same ratio with the frequency of a high-frequency power signal that excites the plasma process. The frequency of the at least one plasma signal of interest and the sampling frequency can be in a specific constant ratio to one another. In some cases, the sampling rate can be tracked at a constant factor relative to the excitation frequency. This allows a simpler architecture for the signal processing.

Particular advantages can be achieved when the plasma signals of interest are digitized merely using a single A/D converter. This makes it possible to save on hardware.

The composite signal can be filtered prior to digitization. The composite signal can be low-pass filtered, band-pass filtered, or high-pass filtered. The filtering makes it possible for the composite signal to be sampled at a lower sampling rate.

The sampling frequency can be changed by a VCO (voltage controlled oscillator) or DDS (direct digital synthesizer). It is thus possible to change the sampling frequency quickly and reliably.

The plasma signal of interest and/or the interfering signal can be determined by digital signal processing.

The digital evaluation can be limited to one frequency by filtering, e.g., by band-pass filtering or by mixing or demodulation. The frequency can be the frequency of the at least one plasma signal of interest. The digital evaluation can also analyze a plurality of frequencies or frequency bands. This can be carried out for example using a plurality of band-pass filters or a plurality of mixers or demodulators, by sweeping a band-pass filter curve over a frequency range, or by a Fourier transform.

In another aspect, the disclosure features devices for carrying out the methods described herein. The devices include an A/D converter to which a digital signal processor is connected, and further include a sampling frequency generator that feeds a sampling frequency to the A/D converter, where the digital signal processor is connected to the sampling frequency generator. The sampling frequency generator can thus generate a suitable sampling frequency, by which the plasma signals of interest can be sampled. The sampling signal or the sampling frequency can be generated on the basis of the analysis of an interfering signal, by digital signal processing.

The sampling frequency generator can include an input for specifying a frequency of a plasma signal of interest. This makes it easier to determine a suitable sampling frequency. It is thus also possible to determine the Nyquist zones of the harmonics and generate a suitable sampling frequency.

The sampling frequency generator can include an input for specifying a frequency of an interfering signal. An interfering signal can first be determined by digital signal processing and, as soon as the interfering signal has been determined, information relating to the interfering signal can be fed to the sampling signal generator so that the sampling signal generator can generate a suitable sampling signal.

Further features and advantages of the invention can be found in the following detailed description of embodiments of the invention, with reference to the drawings which show details of the invention, and in the claims. The features shown therein are not necessarily to scale and are shown such that the particularities according to the invention can be made clearly visible. The different features may each be implemented in isolation or together in any desired combination in variants of the invention.

Embodiments of the invention are shown in the schematic drawings and explained in greater detail in the following description.

DESCRIPTION OF DRAWINGS

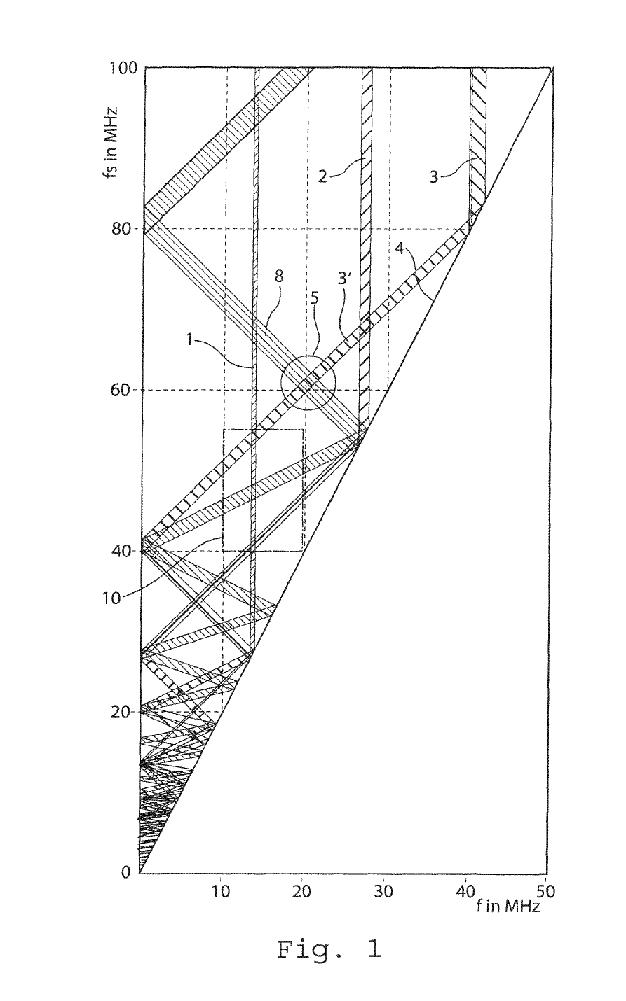

FIG. 1 is a graph showing a sampling frequency vs. a signal spectrum.

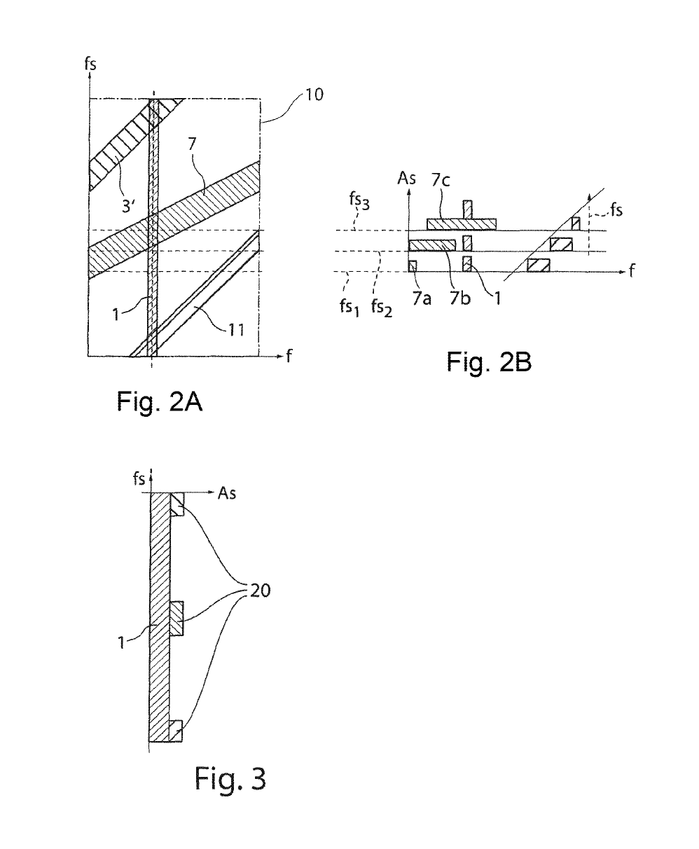

FIG. 2A is an enlarged graph that shows a detail from the graph of FIG. 1.

FIG. 2B is a schematic diagram that shows relative positions of interfering signals and plasma signals of interest for three different sampling frequencies.

FIG. 3 is a schematic diagram that shows a determination of interfering signals on the basis of a frequency sweep of a sampling frequency.

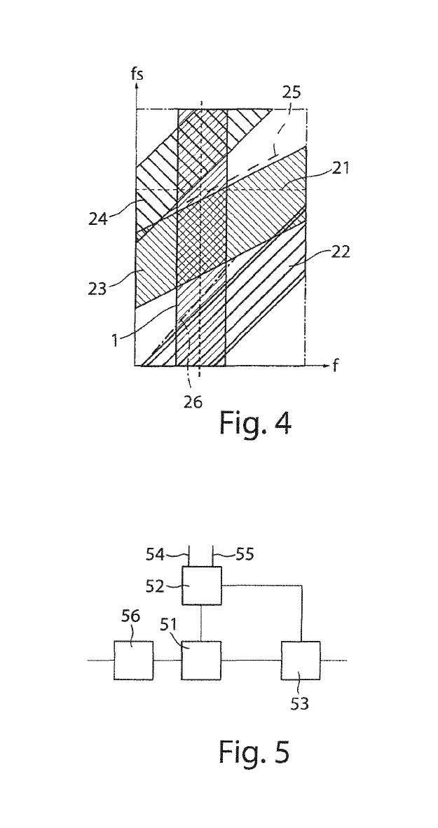

FIG. 4 is a graph that illustrates a variation in a sampling frequency.

FIG. 5 is a schematic block diagram of an example of a device for sampling a plasma signal as described herein.

### DETAILED DESCRIPTION

FIG. 1 shows a spectrum of a frequency range of 0 to 50 MHz for different sampling rates (fs) in a range between 0 and 100 MHz. In the embodiment shown, a plasma process was excited by a high-frequency power signal having a fundamental frequency of 13.56 MHz. The first plasma signal of interest is denoted by reference numeral 1. Since the fundamental frequency can be slightly varied around the nominal value thereof, the reference numeral 1 at the frequency of 13.56 MHz is not just a line, but rather a band.

Further signals relating to the plasma process are signals at harmonics of the high-frequency power signal having the fundamental frequency of 13.56 MHz, e.g., harmonic signals. The first harmonic is at approximately 27 MHz. This is denoted by reference numeral 2. The second harmonic is slightly above 40 MHz and is provided with reference numeral 3. The signals having reference numerals 1, 2, and 3 are, for example, plasma signals of interest. If a sampling frequency of between approximately 85 and 90 MHz is selected, the signals can be unambiguously identified. This is because the Nyquist criterion is fulfilled for these signals, e.g., the sampling rate is more than twice the highest frequency to be sampled. The Nyquist criterion corresponds to the line provided with reference numeral 4. The signal represented by reference numeral 3′ is the alias of the signal represented by reference numeral 3 from the second Nyquist zone. The fifth harmonic of the fundamental frequency is at 81.36 MHz, and the signal shown, having reference numeral 8, is the alias thereof from the third Nyquist zone.

If a lower sampling frequency is to be selected, e.g., a frequency in the region of 60 MHz, it is possible to monitor the fundamental frequency at 13.56 MHz and the first harmonic at 27.12 MHz, but it would not be possible to monitor the second harmonic at 40.68 MHz, which in this case appears as the alias represented by reference numeral 3′ from the second Nyquist zone at approximately 20 MHz, because the alias of the fifth harmonic (represented by reference numeral 8) is superimposed on the alias in the region shown by reference numeral 5. What is known as a distorted plasma signal of interest is formed here for the second harmonic of 40.68 MHz (alias 3′). The Nyquist mirror image of the second harmonic 3′ can thus no longer be unambiguously resolved.

In the following, the region 10, which is shown enlarged in FIG. 2A, will be explained in greater detail. It can be seen in FIG. 2A that the region 10 contains the plasma signal of interest 1 at the excitation frequency or fundamental frequency of 13.56 MHz. Moreover, the region contains a signal 11 that is the alias of the first harmonic 2 at the frequency of approximately 27 MHz, as well as the signal 3′ that is the alias of the signal 3 at the frequency of slightly above 40 MHz. The signals 3′, 11 occur because the sampling frequency is selected to be less than twice the frequencies of the signals 2, 3, and therefore mirroring occurs at half of the sampling frequency. Moreover, at the frequency of 13.56 MHz, an interfering signal 7 is superimposed on the signal 1, which interfering signal is the alias of the fifth harmonic of 81.36 MHz from the 4th Nyquist zone thereof. The signals 3′, 11 are also interfering signals for the signal 1. The signal 1, and likewise the signals of the harmonics, have a particular width since, to control the plasma process, it is possible for the frequency of the high-frequency power signal used for exciting the plasma process to vary within certain limits.

The way in which an interfering signal can be determined on the basis of a spectrum produced in the digital representation and that is obtained at a particular sampling frequency, as shown in FIG. 2A, will be explained with reference to FIG. 2B, where As represents an amplitude of a signal. The signal 1 is free of interference at the sampling frequencies fs1, fs2. The interference components 7a, 7b are next to the plasma signal of interest 1. In the case of the sampling frequency fs3, however, the interfering signal 7c is superimposed on the plasma signal of interest 1. The original frequency or the original frequency range, and thus the Nyquist zone, of the interfering signal 7c, can thus be reconstructed by monitoring the frequency shift. It is thus possible to predict the behavior of the interfering signal 7 when the sampling rate fs is changed, and to prevent superimposition on the plasma signal of interest 1.

Alternatively, according to FIG. 3, a frequency sweep of the sampling frequency can be carried out. For example, in the detail 10 shown, the sampling frequency can be varied between 40 MHz and 55 MHz. In this method, instead of a spectrum, just a single frequency or a frequency band is monitored, which simplifies the digital signal processing. In this case, the interfering signals 20 are then detected by amplitude changes on the monitored frequency. This frequency sweep of the sampling frequency can take place at the start of the plasma process. Alternatively or in addition, the frequency sweep of the sampling frequency can be repeated.

FIG. 2A, 2B and 3 illustrate the identification of interfering signals.

FIG. 4 again shows the signal 1, i.e., the plasma signal of interest. If the sampling frequency is to be selected according to the dotted line 21 for example, the signal 1 could not be sampled free of interference. Interfering signals would always be superimposed on the signal 1. If, however, the interfering signals 22, 23, 24 are known, the sampling rate (or sampling frequency) can be varied according to line 25 for example. In some implementations, the rate or frequency can be varied uniformly with the frequency of the interfering signal 23. Alternatively, the sampling rate can be changed proportionally to the frequency variation of the signal 1, according to line 26. In this case, the sampling rate is changed in the same ratio as the frequency of the signal of interest 1, which signal remains, measured at the sampling rate fs, at the same relative position on the spectrum, and this simplifies the architecture of the digital signal processing. Thus, the signal 1 can be sampled in a region in which interfering signals are not superimposed thereon. To be able to appropriately select the sampling rate according to the lines 25, 26, the interfering signals or the frequencies of the interfering signals must be known. Therefore, according to the invention, the interfering signals are first identified. The manner in which the interfering signals are identified is shown in FIGS. 2A, 2B and 3 for example.

The block diagram in FIG. 5 shows a device 50 for carrying out the methods described herein. A composite signal to be sampled is fed to an A/D convertor 51. A sampling frequency is specified for the A/D convertor 51 by a sampling frequency generator 52, which may include a voltage-controlled oscillator (VCO) or a direct digital synthesizer (DDS). The sampling frequency generator 52 is, in turn, connected to a digital signal processor 53, which can identify interfering signals. On the basis of the interfering signal identified, the sampling frequency generator 52 can determine a corresponding sampling signal or a sampling frequency. Furthermore, the sampling frequency generator 52 includes an input 54 for specifying a frequency of a plasma signal of interest and an input 55 for specifying a frequency of an interfering signal.

Optionally, an analogue filter 56 can be provided for filtering a plasma signal of interest. In this case, the signal is filtered before it is fed to the A/D convertor 51.

### OTHER EMBODIMENTS

A number of embodiments of the invention have been described. Nevertheless, it will be understood that various modifications may be made without departing from the spirit and scope of the invention. Accordingly, other embodiments are within the scope of the following claims.

What is claimed is:

1. A method of sampling a composite signal associated with a plasma process, wherein the composite signal comprises at least one plasma signal of interest on which at least one interfering signal is superimposed, the method comprising:
identifying at least one interfering signal;
digitizing the composite signal by sampling the composite signal at a sampling frequency; and
varying the sampling frequency during operation of the plasma process in dependence on at least one of (i) a frequency of the at least one plasma signal of interest and (ii) a frequency of the at least one interfering signal.

2. The method of claim 1, further comprising:
identifying a plurality of plasma signals of interest at the same sampling frequency based on a result of varying the sampling frequency.

3. The method of claim 1, further comprising:
identifying at least one of (i) the at least one plasma signal of interest and (ii) the at least one interfering signal in a Nyquist zone that is higher than a frequency range up to a half of the sampling frequency.

4. The method of claim 1, further comprising:
determining a digital representation of the frequency of the at least one plasma signal of interest and the frequency of the at least one interfering signal.

5. The method of claim 4, wherein the digital representation is determined by calculation.

6. The method of claim 1, further comprising:
identifying respective digital representations of the frequencies of the at least one plasma signal of interest and of the at least one interfering signal by at least one frequency sweep of the sampling frequency at a start of operation of the plasma process.

7. The method of claim 1, further comprising:
identifying respective digital representations of the frequencies of the at least one plasma signal of interest and of the at least one interfering signal by repeated frequency sweeps of the sampling frequency during operation of the plasma process.

8. The method of claim 1, further comprising:
identifying respective digital representations of the frequencies of the at least one plasma signal of interest and of the at least one interfering signal by modulating the sampling frequency.

9. The method of claim 1, further comprising:
identifying respective digital representations of the frequencies of the at least one plasma signal of interest and of the at least one interfering signal by frequency or amplitude modulation of a high-frequency power signal exciting the plasma process.

10. The method of claim 1, further comprising:
tracking the sampling frequency uniformly with the frequency of the at least one interfering signal.

11. The method of claim 1, further comprising:
tracking the sampling frequency uniformly with the same ratio with a frequency of a high-frequency power signal that excites the plasma process.

12. The method of claim 1, wherein digitizing the composite signal comprises using a single analogue/digital (A/D) convertor.

13. The method of claim 1, further comprising:
filtering the composite signal prior to sampling the composite signal.

14. The method of claim 1, wherein varying the sampling frequency comprises changing the sampling frequency by a voltage-controlled oscillator (VCO) or a direct digital synthesizer (DDS).

15. The method of claim 1, further comprising:
monitoring a frequency shift of the at least one interfering signal when the sampling frequency is varied; and
identifying the at least one interfering signal based on a result of monitoring the frequency shift.

16. The method of claim 1, further comprising:
identifying the at least one plasma signal of interest and the at least one interfering signal based on a result of varying the sampling frequency; and
selecting a particular sampling frequency for sampling the composite signal at which the at least one plasma signal of interest can be detected without the superimposition of the at least one interfering signal.

17. The method of claim 1, wherein the at least one plasma signal of interest comprises a signal that occurs during the plasma process and is to be determined for analyzing or controlling the plasma process.

18. A device for sampling a composite signal associated with a plasma process, wherein the composite signal comprises at least one plasma signal of interest on which the at least one interfering signal is superimposed, the device comprising:
a digital signal processor configured to identify and analyze at least one interfering signal;
a sampling frequency generator connected to the digital signal processor and configured to:
generate a sampling frequency for the composite signal based on a result of analyzing the at least one interfering signal, and
vary the sampling frequency during an operation of the plasma process in dependence on at least one of a frequency of the at least one plasma signal of interest and a frequency of the at least one interfering signal; and
an analogue/digital (A/D) converter connected to the digital signal processor and the sampling frequency generator and configured to:
receive the sampling frequency, and
digitize the composite signal by sampling the composite signal at the sampling frequency.

19. The device of claim 18, wherein the sampling frequency generator comprises an input for specifying a frequency of the plasma signal of interest.

20. The device of claim 18, wherein the sampling frequency generator comprises an input for specifying a frequency of the interfering signal.
